(19) United States
(12) Patent Application Publication
(10) Pub. No.: US 2015/0060253 A1
(43) Pub. Date: Mar. 5, 2015

(54) DECORATIVE SUBSTRATE AND TOUCH PANEL

(71) Applicants: Cheng-Ying Lin, Taichung City (TW); Han-Lun Lin, Changhua County (TW); Chun-Ming Huang, Taichung City (TW); Chun-Chin Chang, Taichung City (TW)

(72) Inventors: Cheng-Ying Lin, Taichung City (TW); Han-Lun Lin, Changhua County (TW); Chun-Ming Huang, Taichung City (TW); Chun-Chin Chang, Taichung City (TW)

(73) Assignee: WINTEK CORPORATION, Taichung City (TW)

(21) Appl. No.: 14/472,337

(22) Filed: Aug. 28, 2014

(30) Foreign Application Priority Data
Aug. 29, 2013 (TW) 102131062

(51) Int. Cl. G06F 1/16; H03K 17/96

(52) U.S. Cl. CPC G06F 1/1692; H03K 17/9622; H03K 2017/9613; H03K 2217/960765
USPC 200/5 R; 428/195.1

(57) ABSTRACT

A decorative substrate and a touch panel are provided. The decorative substrate has a first region and a second region at least partially surrounding the first region. The decorative substrate includes a substrate, a decorative layer and a protective layer. The substrate has a first surface and a first sidewall. The decorative layer is disposed on the first surface and located in the second region. The decorative layer has a second sidewall adjacent to the first sidewall of the substrate, and a portion of the first surface disposed between the second sidewall and the first sidewall is defined as an outer border region. The protective layer is at least partially disposed in the outer border region of the first surface.

### CROSS-REFERENCE TO RELATED APPLICATION

This application claims the priority benefit of Taiwan application serial no. 102131062, filed on Aug. 29, 2013. The entirety of the above-mentioned patent application is hereby incorporated by reference herein and made a part of this specification.

### BACKGROUND OF THE INVENTION

1. Field of the Invention

The invention relates to a substrate and a panel, and more particularly to a decorative substrate and a touch panel.

2. Description of Related Art

As information technology, wireless mobile communication, and information electric appliances rapidly develop in recent years, input devices for many intelligent information electronic products have been changed from conventional keyboards and mice to touch panels for the purposes of convenience, miniaturization, and being user-friendly. Especially, a touch display panel has become the most popular product among all. Current touch panels mainly include capacitive, resistive, photosensitive touch panels, among which the capacitive touch panels are the main stream product.

In a conventional design, a decorative substrate covering on the top of an electronic product and a substrate of the touch panel have the problems of minor cracks on edges and low intensity after the substrate is cut into a predetermined form, thus a secondary strengthening process for the substrate is required to eliminate the cracks on the edges of the substrate. The secondary strengthening process includes performing an acid-etching step on the edges of the substrate after an etching-resistant film is attached on the surface of the substrate. However, after the etching-resistant film is attached, a side etching of an acid solution (e.g., hydrofluoric acid, hydrochloric acid and so on) on the edges of the substrate are prone to extend inwardly during the second strengthening process, resulting in problems of poor appearance such as white borders, black borders or white spots, and even damages and malfunctions to devices.

### SUMMARY OF THE INVENTION

The invention is directed to a decorative substrate capable of solving problems of poor appearance caused by an acid solution during a strengthening process of a substrate.

The invention is further directed to a touch panel capable of providing both ideal strength and ideal appearance.

The invention provides a decorative substrate which has a first region and a second region at least partially surrounding the first region. The decorative substrate includes a substrate, a decorative layer and a protective layer. The substrate has a first surface and a first sidewall. The decorative layer is disposed on the first surface and in the second region. The decorative layer has a second sidewall adjacent to the first sidewall of the substrate, and the first surface disposed between the second sidewall and the first sidewall is defined as an outer border region. The protective layer is at least partially disposed in the outer border region of the first surface.

The invention also provides a touch panel which has a first region and a second region at least partially surrounding the first region. The touch panel includes a substrate, a decorative layer, a conductive structure and a protective layer. The substrate has a first surface and a first sidewall. The conductive structure is disposed on the first surface, and including a first region conductive unit disposed in the first region and a second region conductive unit disposed in the second region. The decorative layer is disposed on the first surface and in the second region. The decorative layer has a second sidewall adjacent to the first sidewall of the substrate, and the first surface disposed between the second sidewall and the first sidewall is defined as an outer border region. The protective layer is at least partially disposed in the outer border region of the first surface.

In an embodiment of the invention, the first region conductive unit includes a plurality of first electrodes electrically insulated to each other.

In another embodiment of the invention, the first region conductive unit further includes a plurality of second electrodes, and the second electrodes are electrically insulated to the first electrodes.

In another embodiment of the invention, the second region conductive unit includes a plurality transmitting lines, and the transmitting lines is connected to the first region conductive unit.

In another embodiment of the invention, the first region conductive unit is composed of the single-layer conductive layer.

In another embodiment of the invention, the first region conductive unit is composed of the multi-layer conductive layer.

In another embodiment of the invention, the multi-layer conductive layer is separated by an insulating member.

In another embodiment of the invention, the protective layer and the insulating member are formed in a same layer.

In each embodiment of the invention, the protective layer has a third sidewall adjacent to the first sidewall of the substrate, and a distance between the third sidewall and the first sidewall is less than 500 μm.

In each embodiment of the invention, the protective layer includes a first portion disposed in the second region and at least one second portion disposed in the outer border region of the first surface.

In each embodiment of the invention, the protective layer includes a first portion covering the decorative layer and at least one second portion disposed in the outer border region of the first surface.

In each embodiment of the invention, the first portion and the at least one second portion including a fourth sidewall and a fifth sidewall, respectively. The at least one second portion is disposed between the first sidewall of the substrate and the fourth sidewall of the first portion, and a distance between the fifth sidewall of the at least one second portion and the first sidewall of the substrate is less than 500 μm.

In each embodiment of the invention, the first portion further extends from the decorative layer to the outer border region, and a width of the at least one second portion is greater than 10 μm.

In each embodiment of the invention, a width of the at least one second portion is greater than 10 μm.

In each embodiment of the invention, a material of the protective layer is identical to a material of the decorative layer.

In each embodiment of the invention, a material of the protective layer is an insulating material.

In each embodiment of the invention, the insulating material includes a silicon nitride, an acid-resistant material, an organic material or an inorganic material.

In each embodiment of the invention, a first etching-resistant film and a second etching-resistant film are further included. The first etching-resistant film covers the first surface of the substrate, and the second etching-resistant film covers a second surface of the substrate on an opposite side of the first surface.

In each embodiment of the invention, a first adhesive layer and a second adhesive layer are further included. The first adhesive layer is disposed between the first etching-resistant film and the first surface of the substrate, and the second adhesive layer is disposed between the second etching-resistant film and the second surface of the substrate.

Based on above, because the decorative substrate and the touch panel of the invention are respectively provided with the protective layer disposed in edge regions adjacent to the sidewalls of the substrate, the side etching of the acid solution (e.g., hydrofluoric acid, hydrochloric acid and so on) during the strengthening process for the substrate can be blocked. Accordingly, devices around the edge regions of the substrate can be protected from corrosion by the acid solution (e.g., hydrofluoric acid, hydrochloric acid and so on), such that the problems of poor appearance can be effectively solved. Moreover, performance of the devices can also be improved.

To make the above features and advantages of the disclosure more comprehensible, several embodiments accompanied with drawings are described in detail as follows.

### BRIEF DESCRIPTION OF THE DRAWINGS

FIG. 1 is a schematic top view of a decorative substrate according to the first embodiment of the invention.

FIG. 2 is a cross-sectional view illustrating the decorative substrate depicted in FIG. 1 along line I-I′.

FIG. 3 is a cross-sectional view of an outer border region of a decorative substrate according to the second embodiment of the invention.

FIG. 4 is a cross-sectional view of an outer border region of a decorative substrate according to the third embodiment of the invention.

FIG. 5 is a cross-sectional view of an outer border region of a decorative substrate according to the fourth embodiment of the invention.

FIG. 6 is a cross-sectional view of an outer border region of a decorative substrate according to the fifth embodiment of the invention.

FIG. 7 is a cross-sectional view of an outer border region of a decorative substrate according to the sixth embodiment of the invention.

FIG. 8 is a schematic top view of a touch panel according to the seventh embodiment of the invention.

FIG. 9 is a schematic top view of a touch panel according to the eighth embodiment of the invention.

FIG. 10 is a schematic top view of a touch panel according to the ninth embodiment of the invention.

FIG. 11 is a schematic top view of a touch panel according to the tenth embodiment of the invention.

### DESCRIPTION OF THE EMBODIMENTS

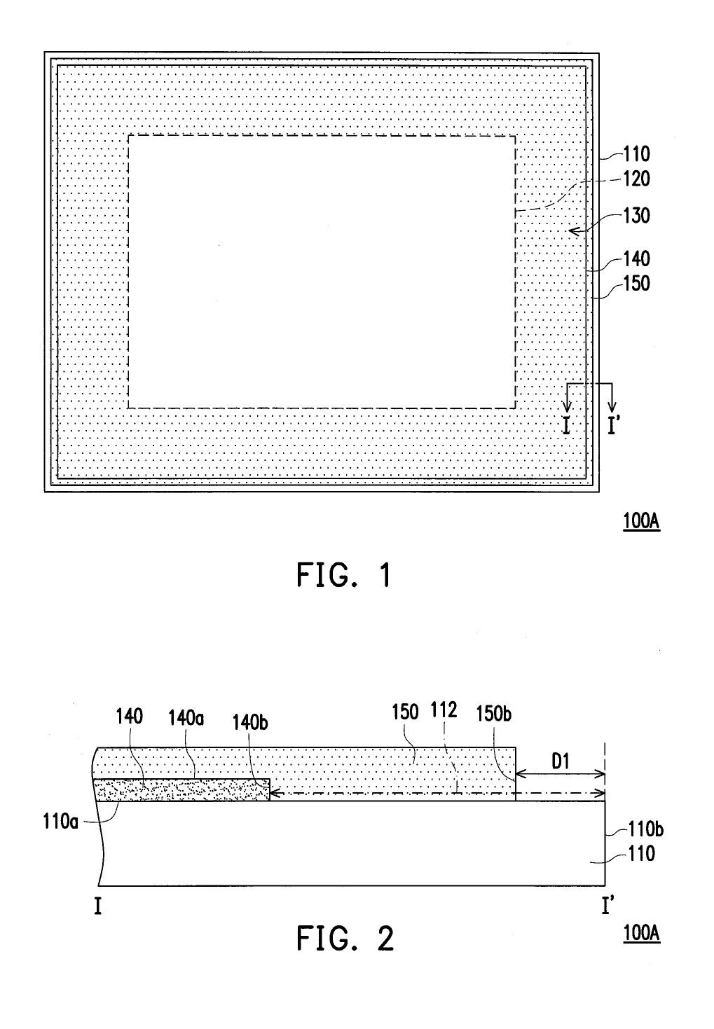

FIG. 1 is a schematic top view of a decorative substrate 100A according to the first embodiment of the invention, and FIG. 2 is a cross-sectional view illustrating the decorative substrate 100A depicted in FIG. 1 along line I-I′.

Referring to FIG. 1 and FIG. 2 together, the decorative substrate 100A has a first region 120 and a second region 130, and the second region 130 surrounds the first region 120. However, the invention is not limited thereto. In other embodiments, the second region 130 can also at least partially surround the first region 120. The decorative substrate 100A includes a substrate 110, a decorative layer 140 and a protective layer 150.

The substrate 110 has a first surface 110a and a first sidewall 110b. Electrodes, wires or other devices can be selectively formed on the substrate 110, but the invention is not limited to said elements. A material of the substrate 110 includes, for example, glass, quartz, an organic polymer (polymeric compound material) or metal, etc.

In view of FIG. 1, the first region 120 being substantially disposed in a center of the substrate 100A can be deemed as a center region, whereas the second region 130 surrounding the first region 120 can be deemed as a peripheral region. The decorative layer 140 is disposed on the first surface 110a and in the second region 130. In the present embodiment, the decorative layer 140 is substantially surrounding the first region 120 without extending in the first region 120. Therefore, the first region 120 can practically be deemed as a region on the substrate 110 which is not disposed with the decorative layer 140 but surrounded by the decorative layer 140. Of course, the invention is not limited thereto. In other embodiments, the decorative layer 140 can merely be disposed on a side of the first region 120 or partially surrounding at periphery of the first region 120.

In view of both FIG. 1 and FIG. 2, the decorative layer 140 has a second sidewall 140b, and the second sidewall 140b is adjacent to the first sidewall 110b of the substrate 110. Further, a portion of the first surface 110a disposed between the second sidewall 140b and the first sidewall 110b is defined as an outer border region 112. In the present embodiment, the outer border region 112 is exposed by the decorative layer 140, for example. In an embodiment of the invention, the decorative substrate 100A disposed with a touch device can serve as a touch panel, and the decorative layer 140 is made of, for example, an ink, a photoresistor, a ceramic, a diamond-like or other materials. Particularly, the decorative layer 140 can be a material layer of black, white, or other colors. However, the invention is not limited thereto. In other embodiments, the decorative substrate 100A can also be applied in other devices excluding the touch panel, such as a display panel, and the decorative layer 140 can also be other appropriate decorative materials.

The protective layer 150 is disposed in the second region 130, and the protective layer 150 covers the decorative layer 140 and is partially disposed in the outer border region 112 of the first surface 110a. More specifically, the protective layer 150 covers an upper surface 140a of the decorative layer 140, extends from the upper surface 140a of the decorative layer 140 to cover the second sidewall 140b, and further extends to a part of the outer border region 112 of the first surface 110a. Further, the protective layer 150 has a third sidewall 150b. The third sidewall 150b is adjacent to the first sidewall 110b of the substrate 110, and a distance D1 between the third sidewall 150b and the first sidewall 110b is less than 500 μm. In other words, the protective layer 150 partially covers the outer border region 112, however, it can also be selected to completely cover the outer border region 112.

Generally, in order to improve a mechanical strength of the decorative substrate 100A and extend an operating life thereof, a subsequent strengthening process is further required after the decorative substrate 100A is manufactured. A common strengthening process utilizes an acid solution (e.g., hydrofluoric acid, hydrochloric acid and so on) to etch the first sidewall 110b, so that cracks on the first sidewall 110b can become smooth, or a roughness of the first sidewall 110b can be further reduced. In other words, the first sidewall 110b can have an etched surface. Nevertheless, in said strengthening process, when the acid solution (e.g., hydrofluoric acid, hydrochloric acid and so on) permeates from the first sidewall 110b toward a center of the substrate 110 (particularly, when an overly side etching occurs), problems of poor appearance such as white borders, black borders or white spots may appear in the outer border region 112. In case the decorative substrate 100A is applied in the touch panel, it is required that a width (which is extended inwardly from the first sidewall 110b) of the white borders, the black borders or the white spots at the borders does not exceed 500 μm.

In the present embodiment, the decorative substrate 100A has the protective layer 150 which covers the decorative layer 140 and extends in a part of the outer border region 112. In addition, a material of the protective layer 150 is, for example, an insulating material. The insulating material includes silicon nitride. The insulating material can also be an acid-resistant material, an organic material or an inorganic material or other appropriate materials. The material of the protective layer 150 can be the insulating material of transparent or non-transparent characteristic, which is not particularly limited in the invention. Accordingly, the edges of the substrate 110 can be protected from the corrosion by the acid solution (e.g., hydrofluoric acid, hydrochloric acid and so on), such that the problems of poor appearance such as the white borders, the black borders or the white spots at the border caused by the side etching can be effectively solved. For instance, the problem of the white border can be solved by disposing and designing of the protective layer 150 of the invention. Particularly, the width of the white border extended inwardly from the first sidewall 110b can be less than 500 μm, so as to meet the existing standard specification.

It should be noted that, in an embodiment of the invention, if at least one insulating layer (not illustrated) is disposed in the first region 120, the protective layer 150 can be formed in the same layer with one of the insulating layers in the first region 120. In other words, the protective layer 150 can be formed by extending one of the insulating layers in the first region 120 to the outer border region 112 and covering the decorative layer 140. Accordingly, a number of utilizing photomask can be prevented from increasing during manufacturing process of the decorative substrate 100A, so as to reduce the costs. In other words, the protective layer 150 can be manufactured by a material layer predetermined to be formed in the first region 120. However, the invention is not limited thereto. In other embodiments, the first region 120 can also be provided without the insulating layer, and the protective layer 150 can also be, for example, an insulating layer exclusively disposed in the second region 130.

In the embodiment of FIG. 2, one single protective layer 150 covers the decorative layer 140 and continue to extend in a part of the outer border region 112, and the distance D1 between the third sidewall 150b and the first sidewall 110b of the substrate 110 is less than 500 μm. However, the invention is not limited thereto. In other embodiments (e.g., second embodiment and third embodiment) of the invention, the protective layer can also include a first portion and a second portion which are separated from each other.

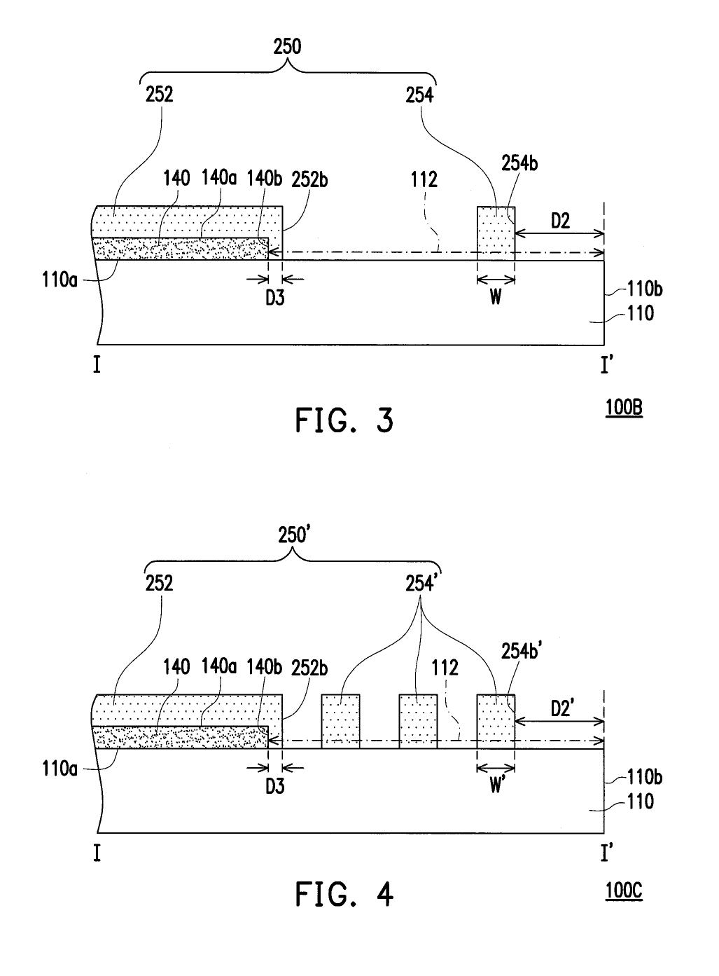

FIG. 3 is a cross-sectional view of an outer border region 112 of a decorative substrate 100B according to the second embodiment of the invention. The embodiment of FIG. 3 is similar to the embodiment of FIG. 2, thus identical or similar elements are indicated by identical or similar reference numbers, and the descriptions thereof are not repeated. A major difference between the embodiment of FIG. 3 and the embodiment of FIG. 2 lies in that, a protective layer 250 of the decorative substrate 100B can include a first portion 252 and a second portion 254 which are separated from each other, and detailed description are described as follows.

The first portion 252 covers the decorative layer 140, and the first portion 252 further extends from the decorative layer 140 to the outer border region 112. The first portion 252 has a fourth sidewall 252b. Further, a distance D3 is provided between the fourth sidewall 252b of the first portion 252 and the second sidewall 140b of the decorative layer 140.

The second portion 254 is disposed in the outer border region 112 of the first surface 110a. In the present embodiment, the second portion 254 is separated from the first portion 252. More specifically, the second portion 254 is disposed between the first sidewall 110b of the substrate 110 and the fourth sidewall 252b of the first portion 252. The second portion 254 has a fifth sidewall 254b adjacent to the first sidewall 110b, and a distance D2 between the fifth sidewall 254b of the second portion 254 and the first sidewall 110b of the substrate 110 is less than 500 μm. In an embodiment, a width W of the second portion 254 is, for example, greater than 10 μm, and more preferably greater than 50 μm.

It should be noted that, the material, the distances D1 to D3 and the width W of the protective layer 250 can be properly selected based on design requirements of the decorative substrate 100B, as long as the protective layer 250 can block the side etching of the acid solution (e.g., hydrofluoric acid, hydrochloric acid and so on) during the subsequent strengthening process for the substrate, so as solve the problems of poor appearance or damages to the substrate 110 and the devices.

FIG. 4 is a cross-sectional view of an outer border region 112 of a decorative substrate 100C according to the third embodiment of the invention. The embodiment of FIG. 4 is similar to the embodiment of FIG. 3, thus identical or similar elements are indicated by identical or similar reference numbers, and the descriptions thereof are not repeated. A major difference between the embodiment of FIG. 4 and the embodiment of FIG. 3 lies in that, a protective layer 250′ of the decorative substrate 100C can include a first portion 252 and a plurality of second portions 254′, and detailed description are described as follows.

The plurality of second portions 254′ are disposed in the outer border region 112 of the first surface 110a, and the second portions 254′ are separated from the first portion 252. More specifically, the plurality of second portions 254′ are disposed between the first sidewall 110b of the substrate 110 and the fourth sidewall 252b of the first portion 252. One of the second portions 254′ adjacent to the first sidewall 110b has a fifth sidewall 254b′ which is closest to the first sidewall 110b, and a distance D2′ between the fifth sidewall 254b′ and the first sidewall 110b of the substrate 110 is less than 500 μm. More specifically, the fifth sidewall 254b′ is a sidewall of the second portion 254′ which is adjacent to the first sidewall 110b of the substrate 110. In an embodiment, widths W′ of the second portions 254′ are, for example, greater than 10 μm, and more preferably greater than 50 μm. The widths W′ of the second portion 254′ can be identical, or different from each other. For instance, the second portion 254′ can include at least two different widths W′. Additionally, in this embodiment it is possible to configure one second portion 254′ at a position (such as shown in FIG. 3) in the outer boarder region 112 and configure plural second portions 254′ at another position (such as shown in FIG. 4) in the outer boarder region 112 according to the design of the decorative substrate 100C.

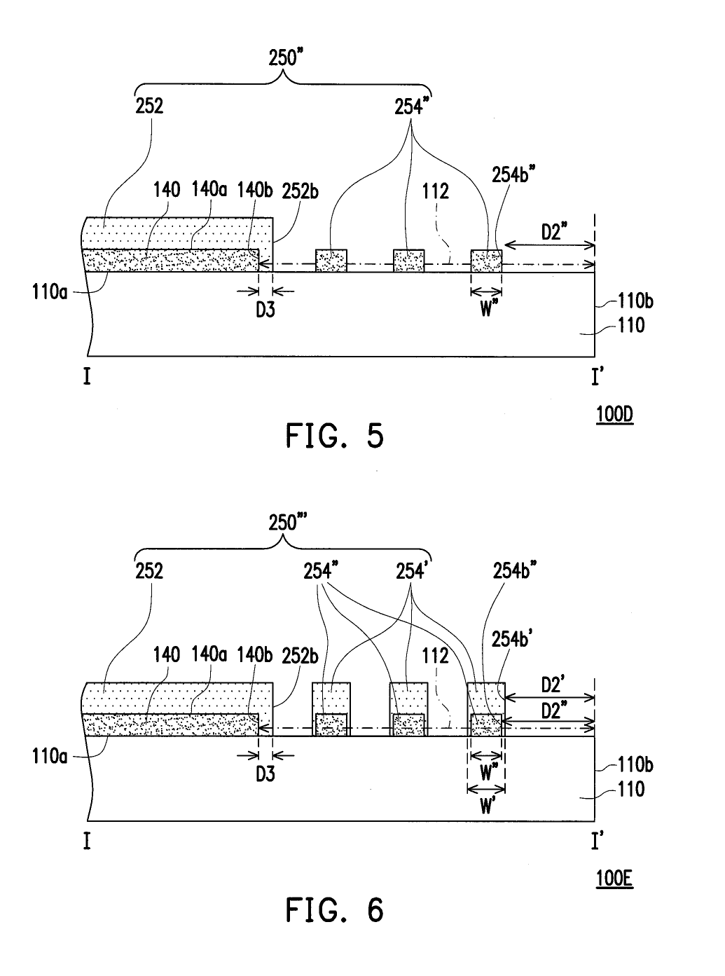

FIG. 5 is a cross-sectional view of an outer border region 112 of a decorative substrate 100D according to the fourth embodiment of the invention. The embodiment of FIG. 5 is similar to the embodiment of FIG. 4, thus identical or similar elements are indicated by identical or similar reference numbers, and the descriptions thereof are not repeated. A major difference between the embodiment of FIG. 5 and the embodiment of FIG. 4 lies in that, a protective layer 250″ of the decorative substrate 100D can include a first portion 252 and a plurality of second portions 254″, and a material of the second portions 254″ is identical to a material of the decorative layer 140, and detailed description are described as follows.

The plurality of second portions 254″ are disposed in the outer border region 112 of the first surface 110a, and the second portions 254″ are separated from the first portion 252. More specifically, the plurality of second portions 254″ is disposed between the first sidewall 110b of the substrate 110 and the fourth sidewall 252b of the first portion 252. One of the second portions 254″ adjacent to the first sidewall 110b has a fifth sidewall 254b″ which is closest to the first sidewall 110b, and a distance D2″ between the fifth sidewall 254b and the first sidewall 110b of the substrate 110 is less than 500 More specifically, the fifth sidewall 254b″ is a sidewall of one second portion 254″ which is adjacent to the first sidewall 110b of the substrate 110. In an embodiment, widths W″ of the second portions 254″ are, for example, greater than 10 μm, and more preferably greater than 50 μm. The widths W″ of the second portion 254″ can be identical to, or different from each other. For instance, the second portion 254″ can include at least two different widths W″. It should be mentioned that, in the present embodiment, the second portions 254″ are, for example, formed by the same manufacturing process of the decorative layer 140 such that the second portions 254″ and the decorative layer 140 are in the same layer. However, the invention is not limited thereto. In other embodiments, the second portion 254″ can also be a layer additionally formed. Further, in the present embodiment, the second portion 254″ having the same material of the decorative layer 140 is served as the protective layer, thus the widths W″ of the second portion 254″ can be smaller than the widths W′ of the second portion 254′. In other words, in case the protective layer uses the same material of the decorative layer, the widths of the protective layer can be manufactured to be narrower, so as to save materials and costs.

FIG. 6 is a cross-sectional view of an outer border region 112 of a decorative substrate 100E according to fifth embodiment of the invention. The embodiment of FIG. 6 is similar to the embodiments of FIG. 4 and FIG. 5, thus identical or similar elements are indicated by identical or similar reference numbers, and the descriptions thereof are not repeated. A major difference between the embodiment of FIG. 6 and the embodiments of FIG. 4 and FIG. 5 lies in that, a protective layer 250′″ can include a first portion 252, a plurality of second portions 254′ and a plurality of second portions 254″. In the present embodiment, it is illustrated with each of the second portions 254′ covering corresponding one of the second portions 254″ as an example, but the invention is not limited thereto. In other embodiments, the second portions 254′ can partially cover the second portions 254″; or the second portions 254′ do not cover the second portions 254″; or there can also be other appropriate configurations.

In the foregoing embodiments of FIG. 2 through FIG. 6, it is illustrated with the protective layer covering the decorative layer and extending in a part of the outer border region as an example. However, the invention is not limited thereto. In other embodiments (e.g., sixth embodiment) of the invention, the decorative substrate can also include other layers such as an etching-resistant film and an adhesive layer, etc.

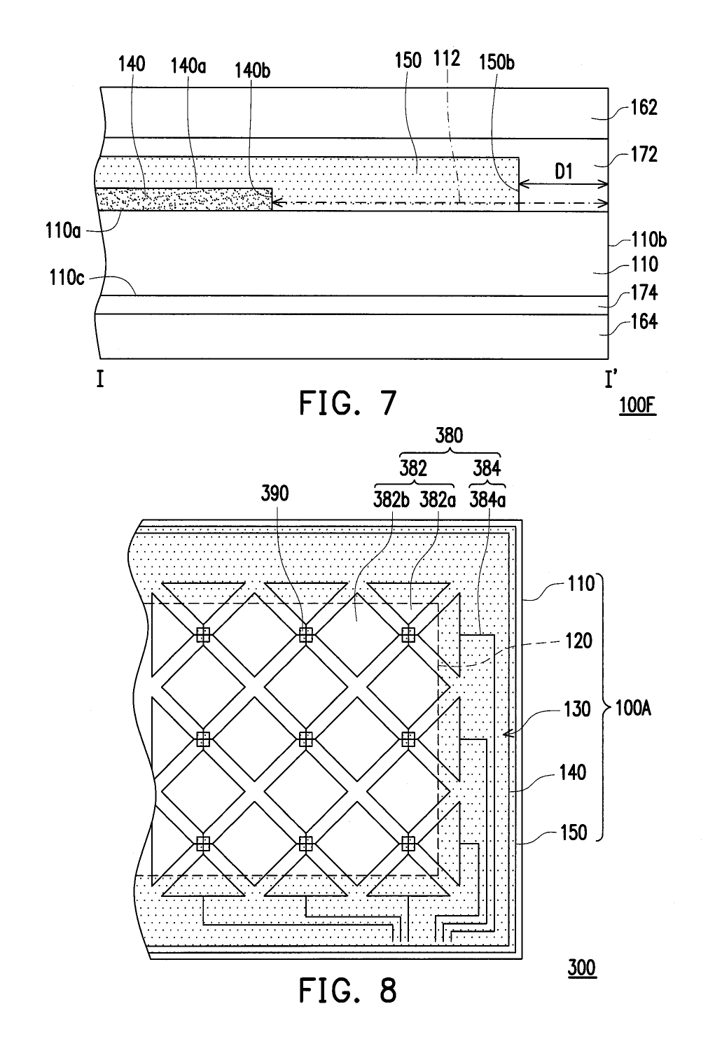

FIG. 7 is a cross-sectional view of an outer border region 112 of a decorative substrate 100F according to the sixth embodiment of the invention. The embodiment of FIG. 7 is similar to the embodiment of FIG. 2, thus identical or similar elements are indicated by identical or similar reference numbers, and the descriptions thereof are not repeated. A major difference between the embodiment of FIG. 7 and the embodiment of FIG. 2 lies in that, the decorative substrate 100F can further include a first etching-resistant film 162, a second etching-resistant film 164, a first adhesive layer 172 and a second adhesive layer 174, and detailed description are described as follows.

The first etching-resistant film 162 covers the first surface 110a of the substrate 110, and the second etching-resistant film 164 covers a second surface 110c of the substrate 110 on an opposite side of the first surface 110a. A material of the first etching-resistant film 162 and the second etching-resistant film 164 includes, for example, polyimide (PI), resin or other appropriate materials.

Further, the first adhesive layer 172 is disposed between the first etching-resistant film 162 and the first surface 110a of the substrate 110, and the second adhesive layer 174 is disposed between the second etching-resistant film 164 and the second surface 110c of the substrate 110. A material of the first adhesive layer 172 and the second adhesive layer 174 includes, for example, an acrylic adhesive or other appropriate materials. The first etching-resistant film 162 and the second etching-resistant film 164 can facilitate in preventing the first surface 110a, the second surface 110c or other devices disposed on said surfaces from corrosion by the acid solution during the strengthening process. In addition, the first etching-resistant film 162, the second etching-resistant film 164, the first adhesive layer 172 and the second adhesive layer 174 can also be applied in any one among the decorative substrates 100A to 100E. In other words, the components in each of the decorative substrates 100A to 100E can be sandwiched between the first etching-resistant film 162 and the second etching-resistant film 164, so as to prevent damages to the decorative layer 140, the first surface 110a or other components during the strengthening process.

Hereinafter, it is further described by using configuration and design of the protective layer of the invention applied in various touch panels as examples, but the invention is not limited by the following embodiments (e.g., seventh embodiment through tenth embodiment).

FIG. 8 is a schematic top view of a touch panel 300 according to the seventh embodiment of the invention. The embodiment of FIG. 8 is similar to the embodiments of FIG. 1 and FIG. 2, thus identical or similar elements are indicated by identical or similar reference numbers, and the descriptions thereof are not repeated.

Referring FIG. 8, the touch panel 300 includes all components of the decorative substrate 100A and a conductive structure 380. The conductive structure 380 is disposed on the first surface 110a of the substrate 110, and including a first region conductive unit 382 disposed in the first region 120 and a second region conductive unit 384 disposed in the second region 130. Herein, position and related description of the first surface 110a can refer to FIG. 2. In addition, the conductive structure 380 of the present embodiment can also be selectively disposed on one of the decorative substrates 100A to 100E recited in the foregoing embodiments, so as to compose a touch panel.

The first region conductive unit 382 includes a plurality of first electrodes 382a and a plurality of second electrodes 382b. The first electrodes 382a are physically separated from each other and electrically insulated to each other; the second electrodes 382b are physically separated from each other and electrically insulated to each other; and the second electrodes 382b are physically separated and electrically insulated to the first electrodes 382a. In the present embodiment, the first electrodes 382a and the second electrodes 382b are respectively composed of a serial structure, and extended along different directions. Hence, the first electrodes 382a and the second electrodes 382b are disposed in an intersecting manner. In order to realize such structure, the first region conductive unit 382 can be composed of a multiple (at least two layers) conductive layer, the multiple conductive layers are separated by an insulating member 390. In other words, the insulating member 390 is disposed between the first electrodes 382a and the second electrodes 382b, and more particularly, the insulating member 390 is disposed at an intersection between the first electrodes 382a and the second electrodes 382b to electrically insulate the first electrodes 382a and the second electrodes 382b, such that a capacitive touch signal therein can be generated during touch operations. A material of the insulating member 390 is, for example, an insulating material. The insulating material includes silicon nitride, an acid-resistant material, an organic material or an inorganic material or other appropriate materials.

In the present embodiment, the protective layer 150 and the insulating member 390 can be formed in the same layer, and manufactured with the same material in the same manufacturing process. However, the invention is not limited thereto. In other embodiment, the touch panel 300 can further include a cover layer (not illustrated) at least covering a portion of the conductive structure 380 and at least being disposed in the first region 120, and the protective layer 150 can selectively be formed in the same layer with the cover layer (not illustrated) or other insulating layers. Therein, a material of the cover layer is, for example, an insulating material. The insulating material includes silicon nitride, an acid-resistant material, an organic material or an inorganic material or other appropriate materials. Furthermore, the cover layer and its configuration can be utilized in any of the following embodiments.

The second region conductive unit 384 includes a plurality transmitting lines 384a. Each of the transmitting lines 384a is connected to the first region conductive unit 380, and more particularly, each of the transmitting lines 384a is connected to one corresponding first electrode 382a or one corresponding second electrode 382b. However, the invention is not limited thereto. In other embodiments, the second region conductive unit 384 can also include other wires or conductive electrodes (e.g., a bonding pad, a self capacitance electrode or electrodes for hovering touch).

In the embodiment of FIG. 8, the first region conductive unit 382 is composed of the multi-layers conductive layer. However, the invention is not limited thereto. In other embodiments (e.g., eighth embodiment through tenth embodiment), the first region conductive unit can also be composed of a single-layer conductive layer.

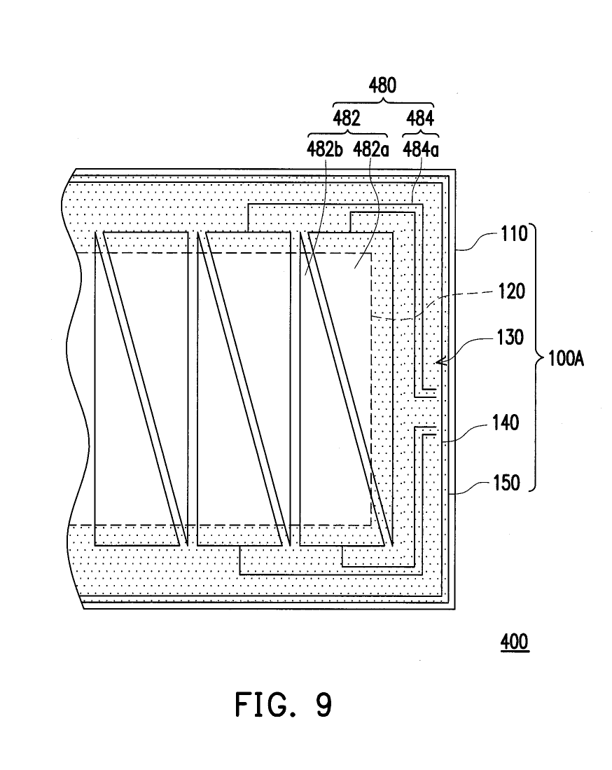

FIG. 9 through FIG. 11 are schematic top views of touch panels 400, 500 and 600 according to the eighth embodiment through the tenth embodiment of the invention. The embodiments of FIG. 9 through FIG. 11 are similar to the embodiment of FIG. 8, thus identical or similar elements are indicated by identical or similar reference numbers, and the descriptions thereof are not repeated.

Referring FIG. 9, the touch panel 400 includes all components of the decorative substrate 100A and further includes a conductive structure 480. The conductive structure 480 is disposed on the first surface 110a, and including a first region conductive unit 482 disposed in the first region 120 and a second region conductive unit 484 disposed in the second region 130. The first region conductive unit 482 includes a plurality of first electrodes 482a and a plurality of second electrodes 482b. The first electrodes 482a are physically separated from each other and electrically insulated to each other; the second electrodes 482b are physically separated from each other and electrically insulated to each other; and the second electrodes 482b are physically separated and electrically insulated to the first electrodes 482a. Herein, positions and related descriptions of the first surface 110a, the first region 120, the second region 130, the decorative layer 140 and the protective layer 150 can refer to FIG. 1 and FIG. 2. In addition, the conductive structure 480 of the present embodiment can also be selectively disposed on one of the decorative substrates 100A and 100E recited in the foregoing embodiments.

In the present embodiment, the first region conductive unit 480 can be composed of the single-layer conductive layer, and the first electrode 482a and the electrode 482b are electrically insulated, such that a capacitive touch signal can be generated therein during touch operations. Furthermore, the second region conductive unit 484 includes a plurality transmitting lines 484a. Each of the transmitting lines 484a is connected to the first region conductive unit 480, and more particularly, each of the transmitting lines 484a is connected to one corresponding first electrode 482a or one corresponding second electrode 482b. In addition, shapes of the first electrode 482a and the second electrode 482b are triangles, and widths of the shapes are changed in opposite tendencies.

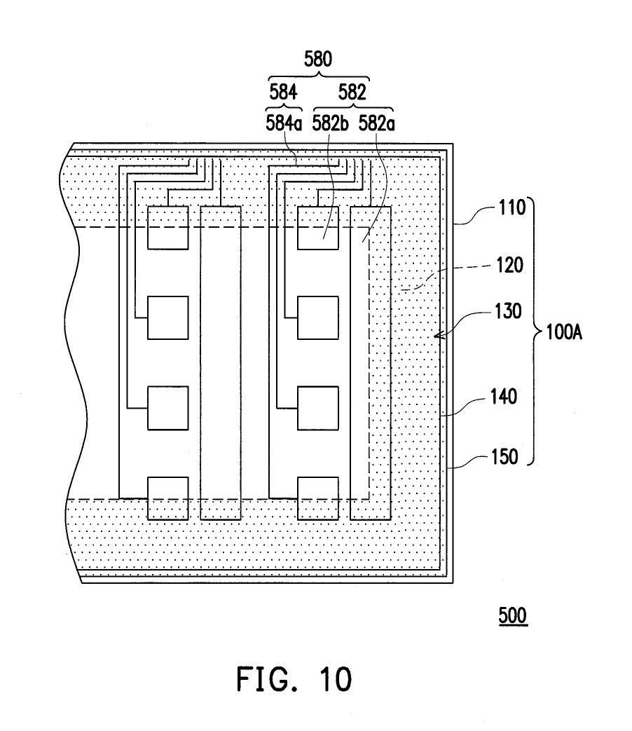

Referring FIG. 10, the touch panel 500 includes all components of the decorative substrate 100A and a conductive structure 580. The conductive structure 580 is disposed on the first surface 110a, and including a first region conductive unit 582 disposed in the first region 120 and a second region conductive unit 584 disposed in the second region 130. Herein, position and related description of the first surface 110a can refer to FIG. 2. In addition, the conductive structure 580 of the present embodiment can also be selectively disposed on one of the decorative substrates 100A and 100E recited in the foregoing embodiments. The first region conductive unit 582 includes a plurality of first electrodes 582a and a plurality of second electrodes 582b. The first electrodes 582a are physically separated from each other and electrically insulated to each other; the second electrodes 582b are physically separated from each other and electrically insulated to each other; and the second electrodes 582b are physically separated and electrically insulated to the first electrodes 582a. In the present embodiment, the first region conductive unit 580 can be composed of the single-layer conductive layer, and the first electrode 582a and the electrode 582b are electrically insulated, such that a capacitive touch signal can be generated therein during touch operations. Herein, each of the first electrodes 582a and the plurality of second electrodes 582b can compose a group for touch sensing. Furthermore, the second region conductive unit 584 includes a plurality transmitting lines 584a, and each of the transmitting lines 584a is connected to one corresponding first electrode 582a or one corresponding second electrode 582b in the first region conductive unit 580.

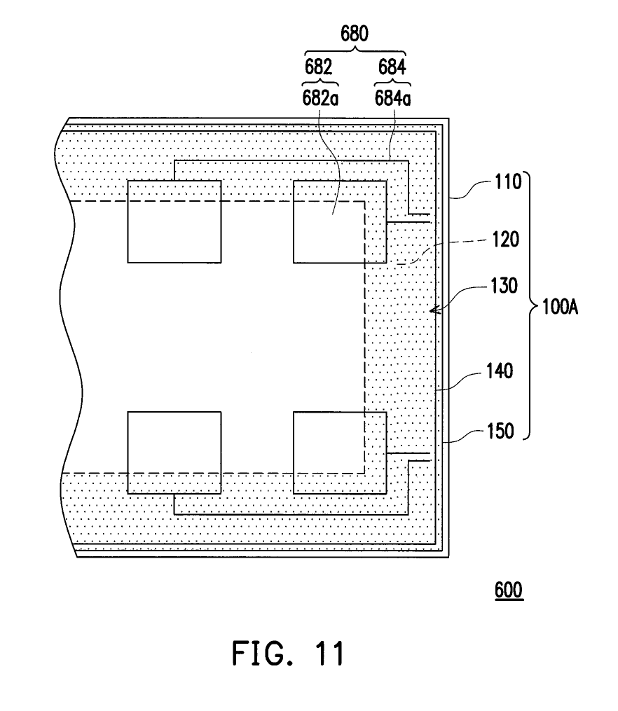

Referring FIG. 11, the touch panel 600 includes all components of the decorative substrate 100 and a conductive structure 680. The conductive structure 680 is disposed on the first surface 110a, and including a first region conductive unit 682 disposed in the first region 120 and a second region conductive unit 684 disposed in the second region 130. Herein, position and related description of the first surface 110a can refer to FIG. 2. In addition, the conductive structure 680 of the present embodiment can also be selectively disposed on one of the decorative substrates 100A and 100E recited in the foregoing embodiments.

The first region conductive unit 682 includes a plurality of electrodes 682a. The electrodes 682a are physically separated from each other and electrically insulated each other. In the present embodiment, the first region conductive unit 680 can be composed of the single-layer conductive layer, and the electrodes 682a are electrically insulated to each other, such that a capacitive touch signal can be generated during touch operations. Furthermore, the second region conductive unit 684 includes a plurality transmitting lines 684a, and each of the transmitting lines 684a is connected to the first region conductive unit 680. In other words, each of the transmitting lines 684a are connected to one corresponding electrode 682a.

In summary, in the decorative substrate and the touch panel of the invention, the protective layer is disposed in the second region, and the protective layer is at least disposed in the outer border region adjacent to the first sidewall of the first surface. Because the decorative substrate and the touch panel of the invention is provided with the protective layer, the side etching of the acid solution (e.g., hydrofluoric acid, hydrochloric acid and so on) during the subsequent strengthening process for the substrate can be blocked. Accordingly, devices around the edges of the substrate can be protected from corrosion by the acid solution (e.g., hydrofluoric acid, hydrochloric acid and so on), such that the problems of poor appearance such as the white borders, the black borders or the white spots at the borders caused by the side etching can be effectively solved. Moreover, performance of the devices can also be improved.

Implementation regarding disposition on surfaces of the substrate in all the foregoing embodiment is not limited to a manner of directly contacting the surfaces of the substrate.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A decorative substrate, comprising a first region and a second region at least partially surrounding the first region, and the decorative substrate comprising:
a substrate having a first surface and a first sidewall;
a decorative layer disposed on the first surface and located in the second region, and the decorative layer having a second sidewall, wherein the second sidewall is adjacent to the first sidewall of the substrate, and a portion of the first surface disposed between the second sidewall and the first sidewall is defined as an outer border region; and
a protective layer at least partially disposed in the outer border region of the first surface.

2. The decorative substrate of claim 1, wherein the protective layer has a third sidewall adjacent to the first sidewall of the substrate, and a distance between the third sidewall and the first sidewall is less than 500 μm.

3. The decorative substrate of claim 1, wherein the protective layer comprises a first portion at least partially disposed in the second region and at least one second portion disposed in the outer border region of the first surface.

4. The decorative substrate of claim 1, wherein the protective layer comprises a first portion at least partially covering the decorative layer, and at least one second portion disposed in the outer border region of the first surface.

5. The decorative substrate of claim 4, wherein the first portion and the at least one second portion comprise a fourth sidewall and a fifth sidewall, respectively, wherein the at least one second portion is disposed between the first sidewall of the substrate and the fourth sidewall of the first portion, and a distance between the fifth sidewall of the at least one second portion and the first sidewall of the substrate is less than 500 μm.

6. The decorative substrate of claim 5, wherein the first portion further extends from where the decorative layer is located to the outer border region, and a width of the at least one second portion is greater than 10 μm.

7. The decorative substrate of claim 5, wherein a width of the at least one second portion is greater than 10 μm.

8. The decorative substrate of claim 3, wherein the at least one second portion has a structure composed of plural layers.

9. The decorative substrate of claim 8, wherein the at least one second portion further comprises a first film layer and a second film layer, wherein the first film layer is disposed between the first surface and the second film layer, and a material of the first film layer is the same as a material of the decorative layer.

10. The decorative substrate of claim 1, wherein a material of the protective layer is identical to a material of the decorative layer.

11. The decorative substrate of claim 1, wherein a material of the protective layer is an insulating material.

12. The decorative substrate of claim 11, wherein the insulating material comprises an acid-resistant material, an organic material or an inorganic material.

13. The decorative substrate of claim 1, further comprising a first etching-resistant film and a second etching-resistant film, wherein the first etching-resistant film covers the first surface of the substrate, and the second etching-resistant film covers a second surface of the substrate on an opposite side of the first surface.

14. The decorative substrate of claim 13, further comprising a first adhesive layer and a second adhesive layer, wherein the first adhesive layer is disposed between the first etching-resistant film and the first surface of the substrate, and the second adhesive layer is disposed between the second etching-resistant film and the second surface of the substrate.

15. The decorative substrate of claim 1, wherein the first sidewall has an etched surface.

16. A touch panel, comprising a first region and a second region at least partially surrounding the first region, and the touch panel comprising:
a substrate having a first surface and a first sidewall;
a conductive structure disposed on the first surface, and comprising a first region conductive unit disposed in the first region and a second region conductive unit disposed in the second region;
a decorative layer disposed on the first surface and located in the second region, and the decorative layer having a second sidewall, wherein the second sidewall is adjacent to the first sidewall of the substrate, and a portion of the first surface disposed between the second sidewall and the first sidewall is defined as an outer border region; and
a protective layer at least partially disposed in the outer border region of the first surface.

17. The touch panel of claim 16, wherein the protective layer has a third sidewall adjacent to the first sidewall of the substrate, and a distance between the third sidewall and the first sidewall is less than 500 μm.

18. The touch panel of claim 16, wherein the protective layer comprises a first portion at least partially disposed in the second region and at least one second portion disposed in the outer border region of the first surface.

19. The touch panel of claim 16, wherein the protective layer comprises a first portion at least partially covering the decorative layer and at least one second portion disposed in the outer border region of the first surface.

20. The touch panel of claim 19, wherein the first portion and the at least one second portion include a fourth sidewall and a fifth sidewall, respectively, wherein the at least one second portion is disposed between the first sidewall of the substrate and the fourth sidewall of the first portion, and a distance between the fifth sidewall of the at least one second portion and the first sidewall of the substrate is less than 500 μm.

21. The touch panel of claim 20, wherein the first portion extends from where the decorative layer is located to the outer border region, and a width of the at least one second portion is greater than 10 μm.

22. The touch panel of claim 20, wherein a width of the at least one second portion is greater than 10 μm.

23. The touch panel of claim 16, wherein a material of the protective layer is identical to a material of the decorative layer.

24. The touch panel of claim 16, wherein a material of the protective layer is an insulating material.

25. The touch panel of claim 24, wherein the insulating material comprises an acid-resistant material, an organic material or an inorganic material.

26. The touch panel of claim 16, further comprising a first etching-resistant film and a second etching-resistant film, wherein the first etching-resistant film covers the first surface of the substrate, and the second etching-resistant film covers a second surface of the substrate on an opposite side of the first surface.

27. The touch panel of claim 26, further comprising a first adhesive layer and a second adhesive layer, wherein the first adhesive layer is disposed between the first etching-resistant film and the first surface of the substrate, and the second adhesive layer is disposed between the second etching-resistant film and the second surface of the substrate.

28. The touch panel of claim 16, wherein the first region conductive unit comprises a plurality of first electrodes physically separated from each other.

29. The touch panel of claim 28, wherein the first region conductive unit further comprises a plurality of second electrodes, and the second electrodes being physically separated from the first electrodes.

30. The touch panel of claim 16, wherein the second region conductive unit comprises a plurality of transmitting lines connected to the first region conductive unit.

31. The touch panel of claim 16, wherein the first region conductive unit is composed of a single-layer conductive layer.

32. The touch panel of claim 16, wherein the first region conductive unit is composed of multiple conductive layers.

33. The touch panel of claim 32, wherein the multiple conductive layers are separated by an insulating member.

34. The touch panel of claim 33, wherein the protective layer and the insulating member are formed in a same layer.

35. The touch panel of claim 16, further comprising a cover layer at least covering a portion of the conductive structure, wherein the protection layer and the cover layer are formed in the same layer.

36. The touch panel of claim 18, wherein the at least one second portion has a structure composed of plural layers.

37. The touch panel of claim 36, wherein the at least one second portion further comprises a first film layer and a second film layer, the first film layer being disposed between the first surface and the second film layer, and a material of the first film layer is the same as a material of the decorative layer.

38. The touch panel of claim 37, further comprising a cover layer at least covering a portion of the conductive structure, wherein a material of the second film layer is the same as a material of the cover layer.

39. The touch panel of claim 37, wherein the first region conductive unit is composed of a plurality of conductive layers, the plurality of conductive layers are separated via an insulation element, and a material of the second film layer is the same as a material of the insulation element.

40. The touch panel of claim 16, wherein the first sidewall has an etched surface.
